(19) United States
(12) Patent Application Publication
(10) Pub. No.: US 2016/0146894 A1
(43) Pub. Date: May 26, 2016

(54) METHOD FOR MEASURING ELECTRIC CAPACITY OF CELL MODULE

(71) Applicant: uPI Semiconductor Corp., Hsinchu County (TW)

(72) Inventors: Kuo-Liang Teng, Hsinchu County (TW); Li-Wei Chen, Hsinchu County (TW)

(21) Appl. No.: 14/751,091

(22) Filed: Jun. 25, 2015

(30) Foreign Application Priority Data
Nov. 20, 2014 (TW) 103140237

(51) Int. Cl. G01R 31/36

(52) U.S. Cl. CPC G01R 31/3651; G01R 31/3624; G01R 31/3682

(57) ABSTRACT

A method for measuring electric capacity of a cell module is provided. A voltage measurement unit is configured to measure an instant voltage of the cell module. A calculation processing unit compares the instant voltage with a fully-charged voltage of the cell module. When the instant voltage is smaller than the fully-charged voltage, the calculation processing unit calculates a cell capacity displaying value of the cell module according to a corresponding threshold capacity, the instant voltage and the fully-charged voltage. The fully-charged voltage is a voltage value of the cell module when an electric capacity of the cell module enters a quasi fully-charged range.

### CROSS-REFERENCE TO RELATED APPLICATION

This application claims the priority benefit of Taiwan application serial no. 103140237, filed on Nov. 20, 2014. The entirety of the above-mentioned patent application is hereby incorporated by reference herein and made a part of this specification.

### BACKGROUND

1. Technical Field

The invention relates to an electronic apparatus having a cell (battery), and particularly relates to a method for measuring electric capacity of a cell module (battery module).

2. Related Art

In order to facilitate users to carry and use, today's portable electronic apparatuses (such as notebooks or smart phones) are generally equipped with a rechargeable cell module, and are configured with a mechanism for measuring an electric capacity of the cell module in real-time. In this way, the user can learn a remained power of the portable electronic apparatus at anytime, so as to determine an available time of the portable electronic apparatus and charge the same in time by using an external power.

While the cell module of the electronic apparatus is charged, the electric capacity of the cell module can be continuously measured. Generally, a coulomb counter is used to measure a charging capacity, so as to monitor a status of electric capacity of the cell module during the charging process. For example, the charging capacity measured by the coulomb counter can be substituted into a following equation (1) to monitor the electric capacity of the cell module. In the equation (1), SOCnew is a cell capacity percentage corresponding to a present time point, SOCold is a cell capacity percentage corresponding to a previous time point, Qcc is a charging capacity of the cell module measured by the coulomb counter, and FCC is a fully-charged capacity (a maximum charging capacity) of the cell module in a fully-charged state:

SOCnew=SOCold+(Qcc/FCC) equation (1)

However, the fully-charged capacity of the cell module is varied along with a temperature of an ambient environment and a connected load, so that it is inevitably to have an error when the equation (1) is used to calculate the cell capacity percentage. Particularly, when the cell module is charged to approach the fully-charged state, the calculated cell capacity percentage is hard to reflect an actual variation of the cell capacity to cause inaccuracy in measurement of the electric capacity. For example, when the cell of the portable electronic apparatus approaches the fully-charged state, it probably stays at a certain capacity percentage (for example, 99%) for a long time without reflecting an actual variation of the cell capacity in time. Alternatively, when the cell of the portable electronic apparatus approaches the fully-charged state, the capacity percentage thereof probably jumps from one value to another within a short time (for example, jumps from 95% to 100% instantaneously).

### SUMMARY

The invention is directed to a method for measuring electric capacity of a cell module, by which estimation of a cell capacity displaying value of the cell module is improved.

An embodiment of the invention provides a method for measuring electric capacity of a cell module. In the method, an instant voltage of the cell module is measured. The instant voltage is compared with a fully-charged voltage of the cell module, where the fully-charged voltage is a voltage value when an electric capacity of the cell module enters a quasi fully-charged range. When the instant voltage is smaller than the fully-charged voltage, a cell capacity displaying value of the cell module is calculated according to a corresponding threshold capacity, the instant voltage and the fully-charged voltage.

An embodiment of the invention provides a method for measuring electric capacity of a cell module. In the method, a charging current of the cell module is measured. The charging current is compared with a fully-charged current of the cell module, where the fully-charged current is a charging current threshold of the cell module when an electric capacity of the cell module enters a fully-charged range. When the charging current is greater than or equal to the fully-charged current, a capacity temporary value of the cell module is set as an initial value, and the capacity temporary value keeps subtracting a capacity step value and the charging current keeps subtracting a current step value until the charging current is smaller than a current threshold, and the capacity temporary value is taken as a cell capacity displaying value of the cell module.

An embodiment of the invention provides a method for measuring electric capacity of a cell module. In the method, an instant voltage and a charging current of the cell module are measured. It is determined whether the cell module enters a first charging mode or a second charging mode according to the instant voltage or the charging current. When the cell module enters the first charging mode, a first algorithm is adopted to calculate a cell capacity displaying value of the cell module. When the cell module enters the second charging mode, a second algorithm different to the first algorithm is adopted to calculate the cell capacity displaying value of the cell module.

According to the above descriptions, in the electric capacity measurement methods, when the cell module is charged, a corresponding capacity measurement method is adopted to calculate an accurate cell capacity according to characteristics of voltage and current of the cell module at that moment. In this way, a measurement error caused by environment temperature and the load during capacity measurement is avoided, so as to improve estimation of the cell capacity displaying value of the cell module.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram illustrating a relationship between current and voltage of a cell module and a cell capacity during a charging process according to an embodiment of the invention.

FIG. 2 is a circuit block schematic diagram of an electric capacity measurement apparatus for a cell module according to an embodiment of the invention.

FIG. 3 is a flowchart illustrating a method for measuring electric capacity of a cell module according to an embodiment of the disclosure.

FIG. 4 is a flowchart illustrating a method for measuring electric capacity of a cell module according to an embodiment of the invention.

FIG. 5 is a flowchart illustrating a method for measuring electric capacity of a cell module according to an embodiment of the invention.

FIG. 6 is a flowchart illustrating a method for measuring electric capacity of a cell module according to an embodiment of the invention.

FIG. 7 is a flowchart illustrating a method for measuring electric capacity of a cell module according to an embodiment of the invention.

### DETAILED DESCRIPTION OF DISCLOSED EMBODIMENTS

A term “couple” used in the full text of the invention (including the claims) refers to any direct and indirect connections. For example, if a first device is described to be coupled to a second device, it is interpreted as that the first device is directly coupled to the second device, or the first device is indirectly coupled to the second device through other devices or connection means. Moreover, wherever possible, components/members/steps using the same referential numbers in the drawings and description refer to the same or like parts. Components/members/steps using the same referential numbers or using the same terms in different embodiments may cross-refer related descriptions.

First, a relationship between current and voltage of a general cell module and a cell capacity when the cell module is charged is described. FIG. 1 is a diagram illustrating a relationship between current and voltage of a cell module and a cell capacity during a charging process according to an embodiment of the invention, in which a vertical axis of FIG. 1 represents voltage value V and current value I, a horizontal axis represents cell capacity CAP. In FIG. 1, a curve S1 represents a voltage curve of the cell module relative to the cell capacity CAP when the cell module is charged, and S2 represents a current curve of the cell module relative to the cell capacity CAP when the cell module is charged.

Referring to FIG. 1, after charging of the cell module is started, when an instant voltage of the cell module is smaller than a fully-charged voltage (for example, 4.2V or other voltage values), the cell module enters a first charging mode, for example, a constant current (CC) charging mode. In the first charging mode, a charging current represented by the curve S2 is maintained to a constant value (for example, 1A, or other current values), and the instant voltage represented by the curve S1 is gradually increased from an initial voltage (for example, 3V or other voltage values). Then, as the cell capacity of the cell module is increased, a voltage rising slope tends to be moderate.

When the instant voltage represented by the curve S1 is increased to the fully-charged voltage (for example, 4.2V) of the cell module, i.e., after the cell capacity CAP reaches a conversion value CV shown in FIG. 1, the cell module enters a second charging mode, for example, a constant voltage (CV) charging mode. In the second charging mode, as the charging process is continued, the charging current represented by the curve S2 is gradually decreased from the original constant value (for example, 1A). When the charging current represent by the curve S2 is decreased to a current threshold (for example, 100 mA or other current values), the cell capacity CAP reaches a fully-charged value CF shown in FIG. 1 to complete charging the cell module.

It should be noticed that a capacity range from the conversion value CV to the fully-charged value CF is referred to as a quasi fully-charged range, and a capacity range approaching the fully-charged value CF (for example, a range within ±1% of the fully-charged value CF) is referred to as a fully-charged range. Therefore, the electric capacity measurement apparatus of the invention provides corresponding methods for measuring electric capacity during the charging process in allusion to different characteristics of the constant current charging mode and the constant voltage charging mode according to the characteristic curve of FIG. 1. Implementation of the electric capacity measurement apparatus of the invention is described below.

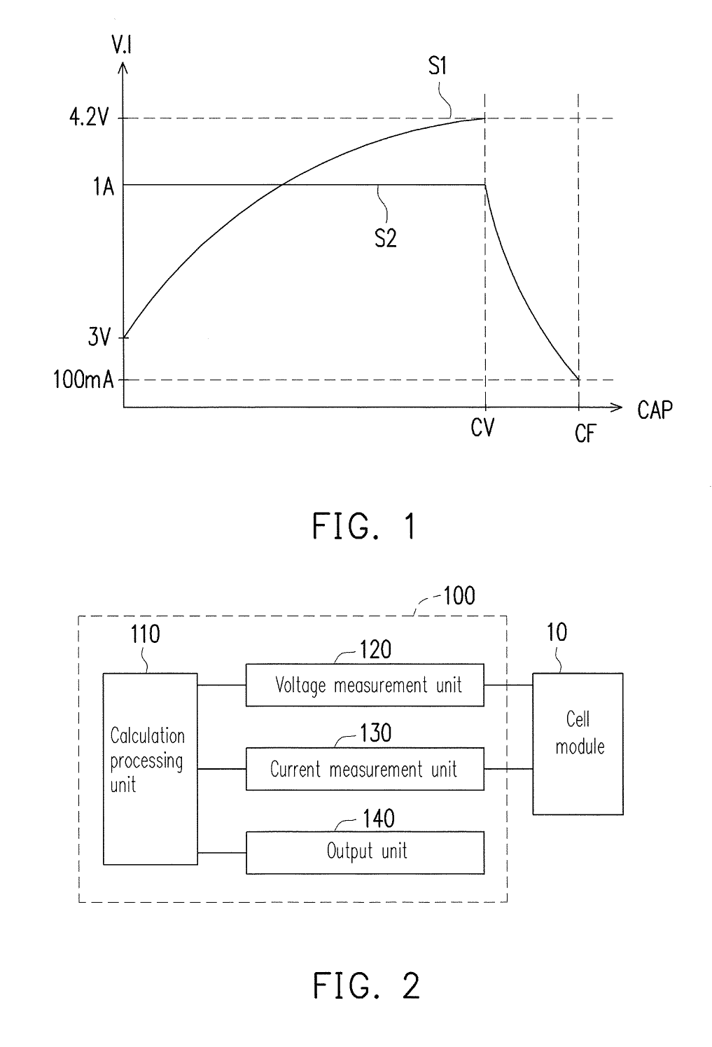

FIG. 2 is a circuit block schematic diagram of an electric capacity measurement apparatus 100 for a cell module according to an embodiment of the invention. Referring to FIG. 2, the electric capacity measurement apparatus 100 is adapted to measure an electric capacity of the cell module 10. The cell module 10 is, for example, a single battery cell (a battery cell unit), or a battery cell group composed of a plurality of battery cells. The electric capacity measurement apparatus 100 includes a calculation processing unit (or a calculation processing circuit) 110, a voltage measurement unit (or a voltage measurement circuit) 120, a current measurement unit (or a current measurement circuit) 130 and an output unit (or an output circuit) 140, and functions thereof are respectively described as follows.

The voltage measurement unit 120 is coupled to the cell module 10. The voltage measurement unit 120 is configured to measure the instant voltage of the cell module 10, and transmits a measuring result to the calculation processing unit 110. The voltage measurement unit 120 can be any type of voltage measurement device/circuit. For example, the voltage measurement unit 120 can be a voltmeter. The current measurement unit 130 is coupled to the cell module 10. The current measurement unit 130 is configured to measure a charging current of the cell module 10, and transmits a measuring result to the calculation processing unit 110. The current measurement unit 130 can be any type of current measurement device/circuit. For example, the current measurement unit 130 can be an amperometer.

The output unit 140 is, for example, a liquid crystal display (LCD), a light-emitting diode (LED) display, a field emission display (FED) capable of reporting a cell capacity displaying value of the cell module 10 in an image display manner, and/or a speaker or a sound equipment capable of generating a sound effect to report the cell capacity displaying value, which is not limited by the invention.

The calculation processing unit 110 is, for example, a central processing unit (CPU) having a single core or multiple cores, or other programmable general purpose or special purpose microprocessor, digital signal processor (DSP), programmable controller, etc. The calculation processing unit 110 is coupled to the voltage measurement unit 120, the current measurement unit 130 and the output unit 140. The calculation processing unit 110 calculates the cell capacity displaying value of the cell module 10 according to a voltage and/or current measured by the voltage measurement unit 120 and/or the current measurement unit 130, and controls the output unit 140 to report the cell capacity displaying value to the user. Detailed steps that the electric capacity measurement apparatus 100 measures the cell capacity are described below.

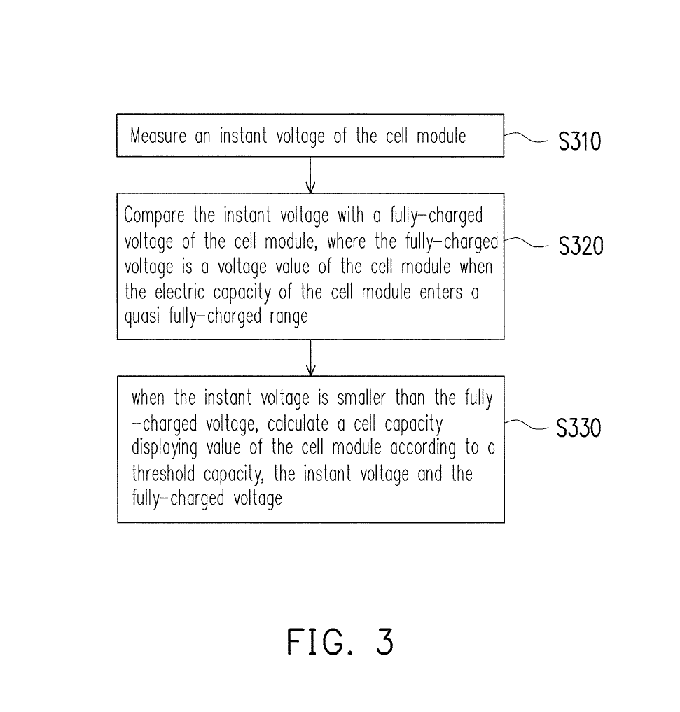

FIG. 3 is a flowchart illustrating a method for measuring electric capacity of a cell module according to an embodiment of the disclosure. Referring to FIG. 1, FIG. 2 and FIG. 3, the method for measuring electric capacity of the present embodiment is adapted to the electric capacity measurement apparatus 100 of FIG. 2, and is adapted to perform corresponding electric capacity measurement in allusion to the constant current charging mode shown in FIG. 1. Various steps of the method for measuring electric capacity of the invention are described below with reference of various components in the electric capacity measurement apparatus 100.

When the cell module 10 is charged, in step S310, the voltage measurement unit 120 measures an instant voltage vol of the cell module 10. In detail, the voltage measurement unit 120 measures the instant voltage vol of the cell module 10 when the cell module 10 is charged, and transmits a measuring result to the calculation processing unit 110.

In step S320, the calculation processing unit 110 compares the received instant voltage vol with a fully-charged voltage t_vol of the cell module 10. The fully-charged voltage t_vol is a voltage value (for example, 4.2V shown in FIG. 1) of the cell module 10 when the electric capacity of the cell module 10 enters the quasi fully-charged range.

When the instant voltage vol is smaller than the fully-charged voltage t_vol, in step S330, the calculation processing unit 110 can calculate a cell capacity displaying value soc of the cell module 10 according to a threshold capacity m_rsoc, the instant voltage vol and the fully-charged voltage t_vol. In detail, as shown in FIG. 1, when the instant voltage vol is smaller than the fully-charged voltage t_vol (for example, 4.2V), the electric capacity of the cell module 10 does not reach the conversion value CV, and the calculation processing unit 110 determines that the cell module 10 is in the constant current charging mode. Now, a charging current curt is maintained to a constant value (for example, 1A), and the calculation processing unit 110 can calculate the cell capacity displaying value soc of the cell module 10 according to the threshold capacity m_rsoc, the instant voltage vol and the fully-charged voltage t_vol of the cell module 10. The threshold capacity m_rsoc is pre-measured. The threshold capacity m_rsoc is the maximum electric capacity of the cell module 10 before the electric capacity of the cell module 10 enters the quasi fully-charged range. Taking the curve diagram of FIG. 1 as an example, the threshold capacity m_rsoc is the conversion value CV. For another example, the threshold capacity m_rsoc can be equal to the constant value maintained by the charging current curt in the constant current charging mode divided by a rated capacity of the cell module 10 times the fully-charged value of the cell module 10, where a magnitude of the rated capacity is determined by a material and a characteristic of the cell module 10, though the invention is not limited thereto.

For example, the calculation processing unit 110 can substitute the threshold capacity m_rsoc, the instant voltage vol and the fully-charged voltage t_vol to a following equation (2) to obtain the cell capacity displaying value soc of the cell module. In the equation (2), stp represents a positive real number. For example, in some embodiments (though the invention is not limited thereto), stp can be the cell capacity displaying value soc of the cell module 10 in a fully-charged state (the fully-charged value) minus the threshold capacity m_rsoc.

soc=m_rsoc−[(t_vol−vol)/stp] equation (2)

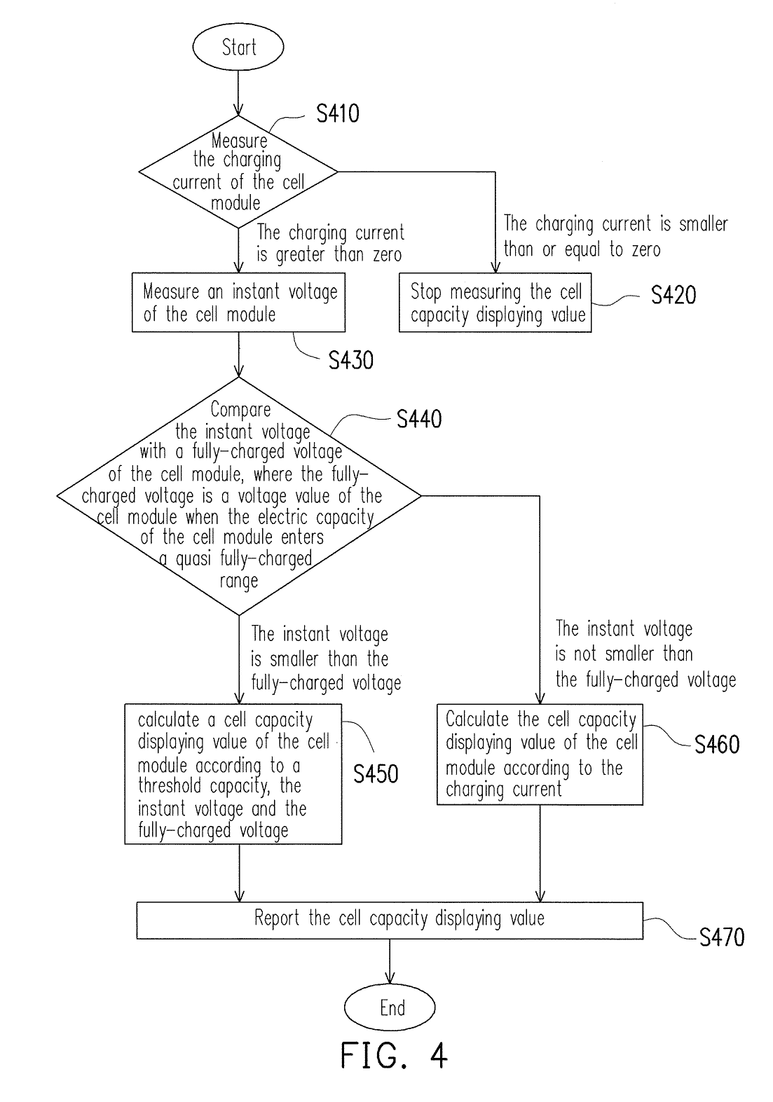

FIG. 4 is a flowchart illustrating a method for measuring electric capacity of a cell module according to an embodiment of the invention. Referring to FIG. 1, FIG. 2 and FIG. 4, the method for measuring electric capacity of the present embodiment is adapted to the electric capacity measurement apparatus 100 of FIG. 2, and is adapted to perform corresponding electric capacity measurement in allusion to the constant current charging mode and the constant voltage charging mode shown in FIG. 1. Various steps of the method for measuring electric capacity of FIG. 4 are described below with reference of various components in the electric capacity measurement apparatus 100.

When the cell module 10 is charged, in step S410, the current measurement unit 130 measures the charging current curt of the cell module 10. In detail, the current measurement unit 130 can measure the charging current curt of the cell module 10 when the cell module 10 is charted, and transmits a measuring result to the calculation processing unit 110. When the calculation processing unit 110 detects that the charging current curt of the cell module 10 is smaller than or equal to zero, in step S420, the electric capacity measurement apparatus 100 stops measuring the cell capacity displaying value soc. In other words, when the cell module 10 is not charged, the electric capacity measurement apparatus 100 of the present embodiment does not measure the cell capacity displaying value soc.

When the calculation processing unit 110 detects that the charging current curt of the cell module 10 is greater than zero, in step S430, the calculation processing unit 110 measures the instant voltage vol of the cell module 10 through the voltage measurement unit 120. In step S440, the calculation processing unit 110 compares the received instant voltage vol with the fully-charged voltage t_vol of the cell module 10. When the instant voltage vol is smaller than the fully-charged voltage t_vol, in step S450, the calculation processing unit 110 calculates the cell capacity displaying value soc according to the corresponding threshold capacity m_rsoc, the instant voltage vol and the fully-charged voltage t_vol. The steps S430, S440 and S450 are the same or similar to the aforementioned steps S310, S320 and S330, so that details thereof are not repeated.

In the present embodiment, when the instant voltage vol is not smaller than the fully-charged voltage t_vol, in step S460, the calculation processing unit 110 calculates the cell capacity displaying value soc of the cell module 10 according to the charging current curt. In detail, as shown in FIG. 1, when the instant voltage vol is not smaller than the fully-charged voltage t_vol, the electric capacity of the cell module 10 has reached the conversion value CV, and the calculation processing unit 110 determines that the cell module 10 is in the constant voltage charging mode. Now, the instant voltage vol is maintained to the fully-charged voltage t_vol, and the calculation processing unit 110 can calculate the cell capacity displaying value soc of the cell module 10 by using the charging current curt.

After the calculation processing unit 110 calculates the cell capacity displaying value soc of the cell module 10 in the step S450 or the step S460, in step S470, the calculation processing unit 110 controls the output unit 140 to report the cell capacity displaying value soc. For example, the calculation processing unit 110 can control the output unit 140 to report the calculated cell capacity displaying value soc to the user through image displaying or sound prompting.

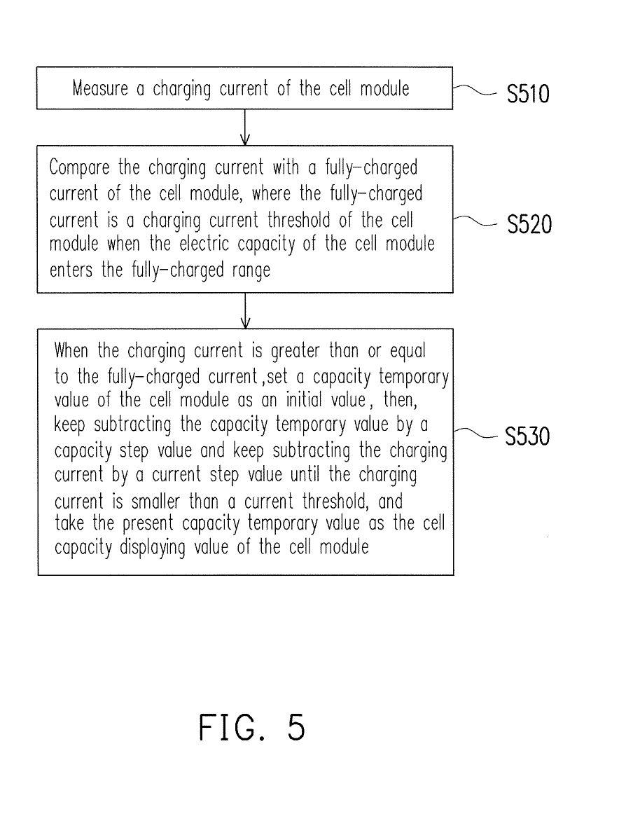

FIG. 5 is a flowchart illustrating a method for measuring electric capacity of a cell module according to an embodiment of the invention. Referring to FIG. 1, FIG. 2 and FIG. 5, the method for measuring electric capacity of the present embodiment is adapted to the electric capacity measurement apparatus 100 of FIG. 2, and is adapted to perform corresponding electric capacity measurement in allusion to the constant voltage charging mode shown in FIG. 1. In some embodiments (though the invention is not limited thereto), implementation detail of the step S460 of FIG. 4 may refer to related description of FIG. 5, and various steps of the method for measuring electric capacity of FIG. 5 are described below with reference of various components in the electric capacity measurement apparatus 100.

When the cell module 10 is charged, in step S510, the current measurement unit 130 measures the charging current curt of the cell module 10. In detail, the current measurement unit 130 can measure the charging current curt of the cell module 10 when the cell module 10 is charted, and transmits a measuring result to the calculation processing unit 110.

In step S520, the calculation processing unit 110 compares the received charging current curt with a fully-charged current t_curt of the cell module 10, where the fully-charged current t_curt is a charging current threshold (for example, 100 mA shown in FIG. 1) of the cell module 10 when the electric capacity of the cell module 10 enters the fully-charged range.

When the charging current curt is greater than or equal to the fully-charged current t_curt, in step S530, the calculation processing unit 110 sets a capacity temporary value soc_t of the cell module 10 as an initial value soc_i (for example, the fully-charged value CF of the cell module 10). Then, the calculation processing unit 110 keeps subtracting the capacity temporary value soc_t by a capacity step value soc_step and keeps subtracting the charging current curt by a current step value curt_step until the charging current curt is smaller than a current threshold curt_thrd, and the present capacity temporary value soc_t is taken as the cell capacity displaying value soc of the cell module 10.

In detail, as shown in FIG. 1, when the charging current curt is greater than or equal to the fully-charged current t_curt, the electric capacity of the cell module 10 has reached the conversion value CV and does not reach the fully-charged value CF, and the calculation processing unit 110 determines that the cell mode 10 is in the constant voltage charging mode. Now, the instant voltage vol is maintained to the fully-charged voltage t_vol, and the calculation processing unit 110 sets the capacity temporary value s_oct of the cell module 10 as the initial value soc_i (for example, the fully-charged value CF of the cell module 10). Then, according to the aforementioned recursive calculation method, the cell capacity displaying value soc is calculated according to the charging current curt.

In some embodiments (though the invention is not limited thereto), the current step value curt_step is, for example, a rated capacity of the cell module 10 divided by the initial value soc_i, and the capacity step value soc_step is, for example, one percent of the fully-charged value CF. A magnitude of the rated capacity is determined by a material and a characteristic of the cell module 10. In another embodiment of the invention, before the calculation processing unit 110 calculates the cell capacity displaying value soc according to the recursive calculation method, the calculation processing unit 110 can first subtract the charging current curt by the fully-charged current t_curt.

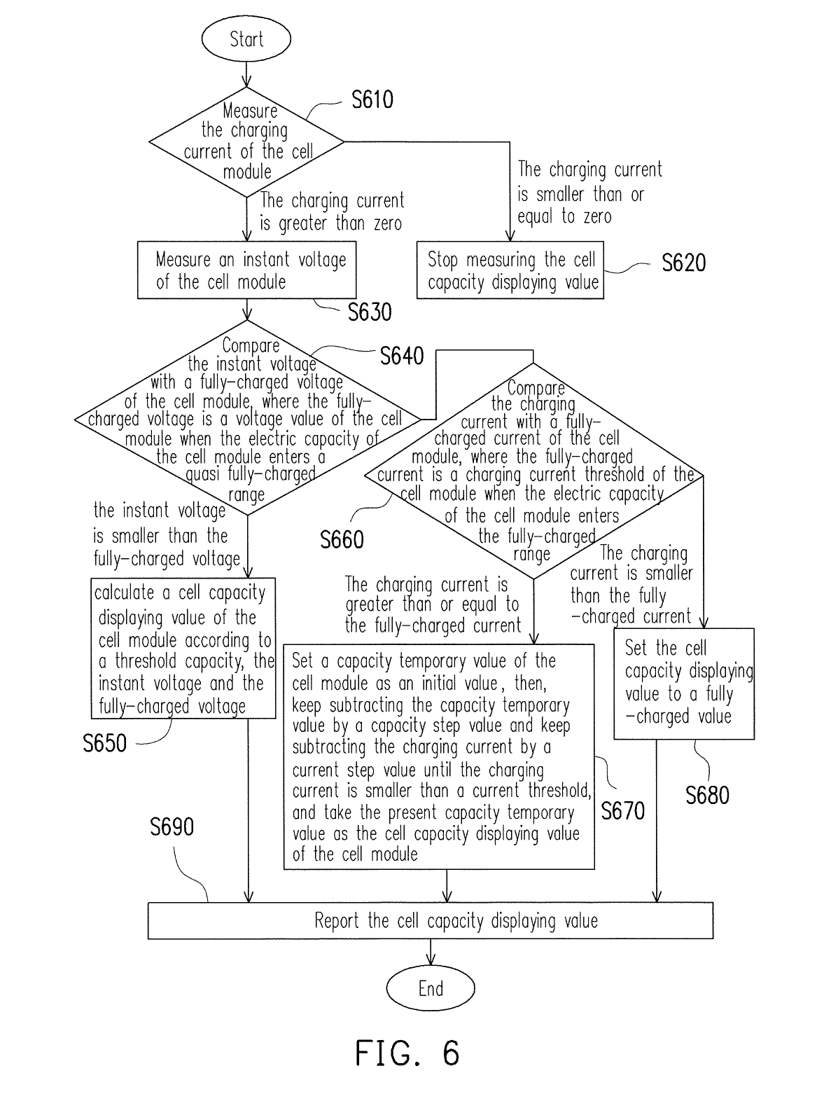

FIG. 6 is a flowchart illustrating a method for measuring electric capacity of a cell module according to an embodiment of the invention. Referring to FIG. 1, FIG. 2 and FIG. 6, the method for measuring electric capacity of the present embodiment is adapted to the electric capacity measurement apparatus 100 of FIG. 2, and is adapted to perform corresponding electric capacity measurement in allusion to the constant current charging mode and the constant voltage charging mode shown in FIG. 1. Various steps of the method for measuring electric capacity of FIG. 6 are described below with reference of various components in the electric capacity measurement apparatus 100.

When the cell module 10 is charged, in step S610, the current measurement unit 130 measures the charging current curt of the cell module 10. When the calculation processing unit 110 detects that the charging current curt of the cell module 10 is smaller than or equal to zero, in step S620, the electric capacity measurement apparatus 100 stops measuring the cell capacity displaying value soc. When the calculation processing unit 110 detects that the charging current curt of the cell module 10 is greater than zero, in step S630, the voltage measurement unit 120 measures the instant voltage vol of the cell module 10.

In step S640, the calculation processing unit 110 compares the received instant voltage vol with the fully-charged voltage t_vol of the cell module 10. When the instant voltage vol is smaller than the fully-charged voltage t_vol, in step S640, the calculation processing unit 110 calculates the cell capacity displaying value soc of the cell module 110 according to the corresponding threshold capacity m_rsoc, the instant voltage vol and the fully-charged voltage t_vol. In step S690, the calculation processing unit 110 controls the output unit 140 to report the cell capacity displaying value soc. The steps S610-S650 and S690 are the same or similar to the steps S410-S450 and S470, so that details thereof are not repeated.

When the instant voltage vol is smaller than the fully-charged voltage t_vol, in step S660, the calculation processing unit 110 compares the received charging current curt with the fully-charged current t_curt of the cell module 10. When the charging current curt is greater than or equal to the fully-charged current t_curt, in step S670, the calculation processing unit 110 sets the capacity temporary value soc_t of the cell module 10 as the initial value soc_i (for example, the fully-charged value CF of the cell module 10). Then, the calculation processing unit 110 keeps subtracting the capacity temporary value soc_t by the capacity step value soc_step and keeps subtracting the charging current curt by the current step value curt_step until the charging current curt is smaller than the current threshold curt_thrd, and the present capacity temporary value s_oct is taken as the cell capacity displaying value soc of the cell module 10. The steps S660 and S670 are the same or similar to the steps S520 and S530 of the aforementioned embodiment, so that details thereof are not repeated.

When the charging current curt is smaller than the fully-charged current t_curt, in step S680, the calculation processing unit 110 sets the cell capacity displaying value soc to the fully-charged value CF (for example, 100%).

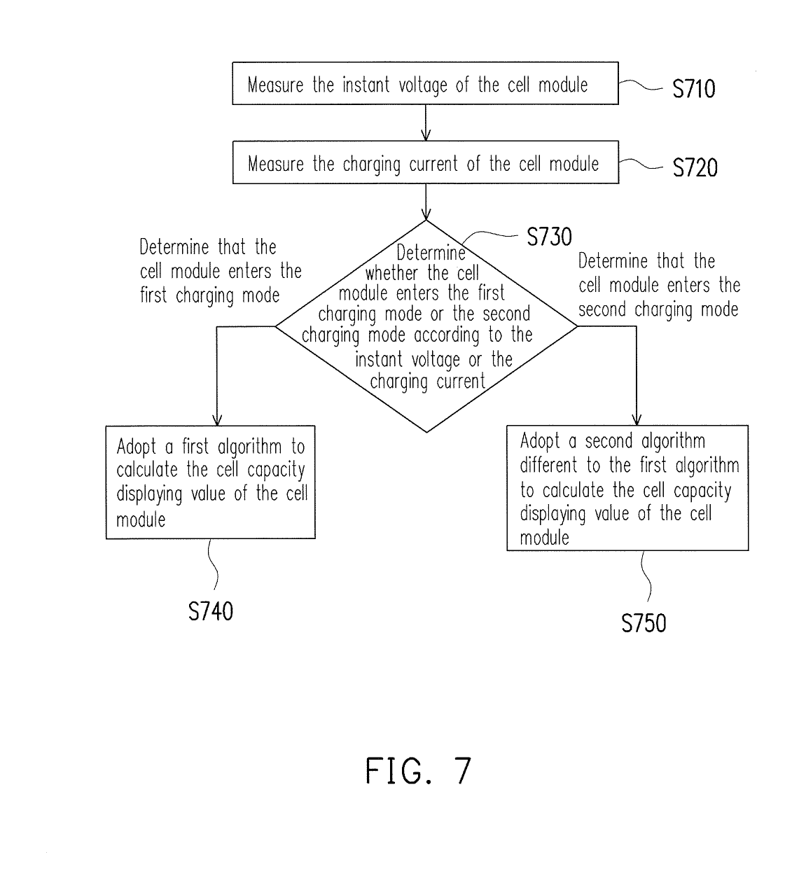

FIG. 7 is a flowchart illustrating a method for measuring electric capacity of a cell module according to an embodiment of the invention. Referring to FIG. 1, FIG. 2 and FIG. 7, the method for measuring electric capacity of the present embodiment is adapted to the electric capacity measurement apparatus 100 of FIG. 2, and is adapted to perform corresponding electric capacity measurement in allusion to the constant current charging mode and the constant voltage charging mode shown in FIG. 1. Various steps of the method for measuring electric capacity of FIG. 7 are described below with reference of various components in the electric capacity measurement apparatus 100.

When the cell module 10 is charged, in step S710, the voltage measurement unit 120 measures the instant voltage vol of the cell module 10, and transmits a measuring result to the calculation processing unit 110. In step S720, the current measurement unit 130 measures the charging current curt of the cell module 10, and transmits a measuring result to the calculation processing unit 110.

In step S730, the calculation processing unit 110 determines whether the cell module 10 enters the first charging mode or the second charging mode according to the received instant voltage vol or the charging current curt. The first charging mode is, for example, the constant current charging mode shown in FIG. 1, and the second charging mode is, for example, the constant voltage charging mode shown in FIG. 1. For example, when the instant voltage vol is smaller than the fully-charged voltage t_vol, the calculation processing unit 110 determines that the cell module 10 enters the first charging mode (i.e., the constant current charging mode), and when the instant voltage vol is not smaller than the fully-charged voltage t_vol and when the charging current curt is greater than or equal to the fully-charged current t_curt, the calculation processing unit 110 determines that the cell module 10 enters the second charging mode (i.e., the constant voltage charging mode).

When the calculation processing unit 110 determines that the cell module 10 enters the first charging mode, in step S740, the calculation processing unit 110 adopts a first algorithm to calculate the cell capacity displaying value soc of the cell module 10. For example (though the invention is not limited thereto), the first algorithm is the method for measuring electric capacity for the constant current charging mode shown in FIG. 3.

When the calculation processing unit 110 determines that the cell module 10 enters the second charging mode, in step S750, the calculation processing unit 110 adopts a second algorithm to calculate the cell capacity displaying value soc of the cell module 10. For example (though the invention is not limited thereto), the second algorithm is the method for measuring electric capacity for the constant voltage charging mode shown in FIG. 5.

In other embodiments of the invention, the electric capacity measurement apparatus 100 for the cell module 10 in FIG. 2 may further include a coulomb counter (not shown). The coulomb counter (not shown) is, for example, coupled to the calculation processing unit 110. The calculation processing unit 110 can measure a charging capacity of the cell module 10 by using the coulomb counter (not shown), and calculate the cell capacity displaying value soc according to the charging capacity. Implementation and operation of the coulomb counter (not shown) are known by those skilled in the art, so that detail thereof is not repeated.

In some embodiments, the first algorithm mentioned in the step S740 is, for example, to use the calculation processing unit 110 to control the coulomb counter (not shown) to measure the charging capacity of the cell module 10, and calculate the cell capacity displaying value soc according to the charging capacity. For example, the calculation processing unit 110 substitutes the charging capacity measured by the coulomb counter to the equation (1) to calculate the cell capacity displaying value soc. The second algorithm mentioned in the step S750 is, for example, the aforementioned method for measuring electric capacity for the constant voltage charging mode shown in FIG. 5.

In other embodiments, the first algorithm mentioned in the step S740 is, for example, the aforementioned method for measuring electric capacity for the constant current charging mode shown in FIG. 3. The second algorithm mentioned in the step S750 is, for example, to use the calculation processing unit 110 to control the coulomb counter (not shown) to measure the charging capacity of the cell module 10, and calculate the cell capacity displaying value soc according to the charging capacity. For example, the calculation processing unit 110 substitutes the charging capacity measured by the coulomb counter to the equation (1) to calculate the cell capacity displaying value soc.

In summary, in the electric capacity measurement apparatus and the method for measuring electric capacity, when the cell module is charged, a corresponding capacity measurement method is adopted to calculate an accurate cell capacity according to characteristics of voltage and current of the cell module presented during the charging process. In this way, a measurement error caused by environment temperature and the load during capacity measurement is avoided.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A method for measuring electric capacity of a cell module, comprising:
measuring an instant voltage of the cell module;
comparing the instant voltage with a fully-charged voltage of the cell module, wherein the fully-charged voltage is a voltage value of the cell module when an electric capacity of the cell module enters a quasi fully-charged range; and
calculating a cell capacity displaying value of the cell module according to a threshold capacity, the instant voltage and the fully-charged voltage when the instant voltage is smaller than the fully-charged voltage.

2. The method for measuring electric capacity of the cell module as claimed in claim 1, further comprising:
measuring a charging current of the cell module; and
stopping measuring the cell capacity displaying value when the charging current is smaller than or equal to zero.

3. The method for measuring electric capacity of the cell module as claimed in claim 1, wherein the step of calculating the cell capacity displaying value of the cell module comprises:
calculating soc=m_rsoc−[(t_vol−vol)/stp] to obtain the cell capacity displaying value soc of the cell module, wherein m_rsoc represents the threshold capacity, t_vol represents the fully-charged voltage, vol represents the instant voltage, and stp represents a positive real number.

4. The method for measuring electric capacity of the cell module as claimed in claim 3, wherein stp is the cell capacity displaying value of the cell module in a fully-charged state minus the threshold capacity.

5. The method for measuring electric capacity of the cell module as claimed in claim 1, further comprising:
reporting the cell capacity displaying value.

6. The method for measuring electric capacity of the cell module as claimed in claim 1, further comprising:
measuring a charging current of the cell module; and
calculating the cell capacity displaying value of the cell module according to the charging current when the instant voltage is not smaller than the fully-charged voltage.

7. The method for measuring electric capacity of the cell module as claimed in claim 6, wherein the step of calculating the cell capacity displaying value of the cell module according to the charging current comprises:
setting a capacity temporary value of the cell module as an initial value when the charging current is greater than or equal to a fully-charged current, wherein the fully-charged current is a charging current threshold of the cell module when the electric capacity of the cell module enters a fully-charged range; and
keeping subtracting the capacity temporary value by a capacity step value and keeping subtracting the charging current by a current step value until the charging current is smaller than a current threshold, and taking the capacity temporary value as the cell capacity displaying value of the cell module.

8. The method for measuring electric capacity of the cell module as claimed in claim 7, wherein the current step value is a rated capacity of the cell module divided by the initial value.

9. The method for measuring electric capacity of the cell module as claimed in claim 7, further comprising:
setting the cell capacity displaying value to a fully-charged value when the charging current is smaller than the fully-charged current.

10. A method for measuring electric capacity of a cell module, comprising:
measuring a charging current of the cell module;
comparing the charging current with a fully-charged current of the cell module, wherein the fully-charged current is a charging current threshold of the cell module when an electric capacity of the cell module enters a fully-charged range; and
setting a capacity temporary value of the cell module as an initial value when the charging current is greater than or equal to the fully-charged current, and keeping subtracting the capacity temporary value by a capacity step value and keeping subtracting the charging current by a current step value until the charging current is smaller than a current threshold, and taking the capacity temporary value as a cell capacity displaying value of the cell module.

11. The method for measuring electric capacity of the cell module as claimed in claim 10, wherein the current step value is a rated capacity of the cell module divided by the initial value.

12. The method for measuring electric capacity of the cell module as claimed in claim 10, further comprising:
setting the cell capacity displaying value to a fully-charged value when the charging current is smaller than the fully-charged current.

13. The method for measuring electric capacity of the cell module as claimed in claim 10, after the step of measuring the charging current of the cell module, the method for measuring electric capacity further comprises:
stopping measuring the cell capacity displaying value when the charging current is smaller than or equal to zero.

14. The method for measuring electric capacity of the cell module as claimed in claim 10, further comprising:
measuring an instant voltage of the cell module; and
performing the operation of subtracting the capacity temporary value by the capacity step value to obtain the cell capacity displaying value of the cell module when the instant voltage is not smaller than a fully-charged voltage, wherein the fully-charged voltage is a voltage value of the cell module when the electric capacity of the cell module enters a fully-charged range.

15. The method for measuring electric capacity of the cell module as claimed in claim 10, wherein after the step of obtaining the cell capacity displaying value of the cell module, the method for measuring electric capacity further comprises:
reporting the cell capacity displaying value.

16. The method for measuring electric capacity of the cell module as claimed in claim 10, further comprising:
measuring an instant voltage of the cell module;
calculating the cell capacity displaying value of the cell module according to a threshold capacity, the instant voltage and the fully-charged voltage when the instant voltage is smaller than a fully-charged voltage, wherein the fully-charged voltage is a voltage value of the cell module when the electric capacity of the cell module enters a quasi fully-charged range.

17. The method for measuring electric capacity of the cell module as claimed in claim 16, wherein the threshold capacity is a maximum electric capacity of the cell module before the electric capacity of the cell module enters the quasi fully-charged range.

18. The method for measuring electric capacity of the cell module as claimed in claim 16, wherein when the electric capacity of the cell module does not enter the quasi fully-charged range, a charging current of the cell module is maintained to a constant value, and the threshold capacity is equal to the constant value divided by a rated capacity of the cell module times a fully-charged value.

19. The method for measuring electric capacity of the cell module as claimed in claim 16, wherein the step of calculating the cell capacity displaying value of the cell module comprises:
calculating soc=m_rsoc−[(t_vol−vol)/stp] to obtain the cell capacity displaying value soc of the cell module, wherein m_rsoc represents the threshold capacity, t_vol represents the fully-charged voltage, vol represents the instant voltage, and stp represents a positive real number.

20. The method for measuring electric capacity of the cell module as claimed in claim 19, wherein stp is the cell capacity displaying value of the cell module in a fully-charged state minus the threshold capacity.

21. A method for measuring electric capacity of a cell module, comprising:
measuring an instant voltage of the cell module;
measuring a charging current of the cell module;
determining whether the cell module enters a first charging mode or a second charging mode according to the instant voltage or the charging current;
adopting a first algorithm to calculate a cell capacity displaying value of the cell module when the cell module enters the first charging mode; and
adopting a second algorithm different to the first algorithm to calculate the cell capacity displaying value of the cell module when the cell module enters the second charging mode.
